(19) United States
(12) Patent Application Publication
(10) Pub. No.: US 2026/0235673 A1
(43) Pub. Date: Aug. 13, 2026

(54) TEST TIME OPTIMIZATION FOR IDENTICAL SUBSYSTEMS IN SOC

(71) Applicant: STMicroelectronics International N.V., Geneva (CH)

(72) Inventor: Harish Kumar, Noida (IN)

(21) Appl. No.: 19/048,542

(22) Filed: Feb. 7, 2025

(51) Int. Cl. G01R 31/3185; G01R 31/317; G01R 31/319

(52) U.S. Cl. CPC G01R 31/318533; G01R 31/31723; G01R 31/31919

(57) ABSTRACT

According to an embodiment, a test architecture for system-on-chip (SoC) enables testing of replicated blocks while maintaining comprehensive fault detection. The architecture includes parallel test pattern application to multiple identical blocks through modified scan logic, with responses compared through both AND-gate and XOR-gate based networks. The AND-gate network provides quick pass/fail indication, while the XOR-gate network prevents fault masking by detecting mismatches between corresponding outputs. A multiplexer enables individual block observation during debug operations.

### TECHNICAL FIELD

The present disclosure generally relates to design for testing and, in particular embodiments, to test time optimization for identical subsystems in system-on-chip.

### BACKGROUND

Modern System-on-Chip (SoC) designs frequently incorporate multiple identical subsystems and components replicated across the chip. These identical subsystems may include processing cores, memory blocks, or other functional circuits laid out and duplicated multiple times using the same design. Replicating identical subsystems helps enable parallel processing capabilities and improved overall system performance.

Test time optimization remains an important consideration in SoC manufacturing, as longer test times directly affect production costs and throughput. Modern semiconductor testing methodologies continue to focus on efficiently testing multiple identical subsystems while maintaining debug capabilities and fault detection coverage.

### SUMMARY

Technical advantages are generally achieved by embodiments of this disclosure, which describe test time optimization for identical subsystems in system-on-chip.

A first aspect relates to a system-on-chip (SoC), comprising a plurality of identical replicated blocks, each block having a plurality of scan outputs; a first comparison network comprising a plurality of AND gates, each AND gate having inputs coupled to corresponding scan outputs from the replicated blocks, a first multiplexer having inputs coupled to outputs of the AND gates and to individual scan outputs from the replicated blocks, and a first flip-flop having an input coupled to an output of the first multiplexer; and a second comparison network comprising a plurality of XOR gates, each XOR gate having inputs coupled to corresponding scan outputs from pairs of the replicated blocks, an OR gate having inputs coupled to outputs of the XOR gates, and a second flip-flop having an input coupled to an output of the OR gate.

A second aspect relates to a method of testing replicated blocks in a system-on-chip (SoC), the method comprising generating test patterns for a first replicated block; simultaneously applying the test patterns to a plurality of identical replicated blocks through modified scan logic; performing first comparisons of corresponding scan outputs through AND gates; performing second comparisons of corresponding scan outputs through XOR gates; combining outputs of the XOR gates through an OR gate; capturing results of the first comparisons in a first flip-flop; capturing results of the second comparisons in a second flip-flop; and evaluating test results based on outputs of both flip-flops.

A third aspect relates to a design for test (DFT) architecture for testing a system-on-chip (SoC) with a plurality of scan chains distributed across identical replicated blocks, the DFT architecture comprising a first comparison network providing parallel test capability through AND gates coupled to corresponding scan outputs from the replicated blocks; a second comparison network preventing fault masking through XOR gates coupled to corresponding scan outputs from pairs of the replicated blocks; selection logic enabling individual observation of replicated block outputs during debug operations; and capture logic registering results from both comparison networks.

### BRIEF DESCRIPTION OF THE DRAWINGS

For a more complete understanding of the present disclosure and the advantages thereof, reference is now made to the following descriptions taken in conjunction with the accompanying drawings, in which:

FIG. 1 is a block diagram of an example system-on-chip (SoC);

FIG. 2 is a test architecture for an embodiment system-on-chip (SoC) that efficiently tests replicated processor blocks;

FIG. 3 is an enhanced test architecture for an embodiment system-on-chip (SoC) that implements XOR-based comparison logic for testing replicated processor blocks;

FIG. 4 is an example timing diagram showing the temporal relationships between various signals in the test architecture;

FIG. 5 is a flowchart of an embodiment method for operating a test architecture;

FIG. 6 is a flowchart of an embodiment method for operating the XOR-based test architecture; and

FIG. 7 is a flowchart of an embodiment method that combines the advantages of AND-gate and XOR-gate based architectures.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise. Various embodiments are illustrated in the accompanying drawing figures, where identical components and elements are identified by the same reference number, and repetitive descriptions are omitted for brevity.

Variations or modifications described in one of the embodiments may also apply to others. Further, various changes, substitutions, and alterations can be made herein without departing from the spirit and scope of this disclosure as defined by the appended claims.

While the inventive aspects are described primarily in the context of testing identical processor cores in system-on-chip designs, it should also be appreciated that they may also apply to testing any identical subsystems or circuits replicated within an integrated circuit. In particular, aspects of this disclosure may similarly apply to testing identical memory blocks, peripheral interfaces, communication blocks, or other functional circuit blocks duplicated multiple times within a semiconductor device.

Embodiments of the disclosure provide systems and techniques for parallel testing of identical subsystems within system-on-chip architectures. The test patterns generated for testing one subsystem can be applied simultaneously to multiple identical subsystems through modified scan logic that propagates the same patterns to all subsystems under test.

In embodiments, AND gates combine the scan outputs from corresponding points in identical subsystems. Pipe flip-flops latch the AND gate outputs to maintain proper timing and synchronization as signals propagate toward the scan-out pads. The latched AND gate outputs allow observation of the combined test responses through the scan-out pads.

To enhance fault detection capabilities, XOR gates can be employed to compare the corresponding scan outputs between identical subsystems. When scan outputs differ between subsystems, indicating potential faults, the XOR gates generate logic high outputs. An OR gate combines the XOR outputs with the OR gate output routed to a dedicated scan-out pad. The OR gate output can provide an additional failure detection mechanism that can identify faults even in cases where the AND gate combinations may mask certain failure conditions, such as when an expected value is ‘0’and one subsystem outputs a faulty ‘1’.

Debug operations remain accessible through multiplexer circuits that allow the selection of scan outputs from individual subsystems. When faults are detected through either the AND gate outputs or the XOR-OR combination, the multiplexers can be configured to pass through scan outputs from a single selected subsystem while test patterns are reapplied. This selective observation enables fault isolation to specific subsystems.

Advantageously, the parallel testing architecture reduces overall test time by eliminating the need to observe each subsystem's outputs in separate test cycles while maintaining thorough fault detection through the combined AND and XOR comparison logic. In embodiments, the approach requires one additional scan-out pad beyond the conventional scan architecture to support XOR-based fault detection. These and additional details are further discussed below.

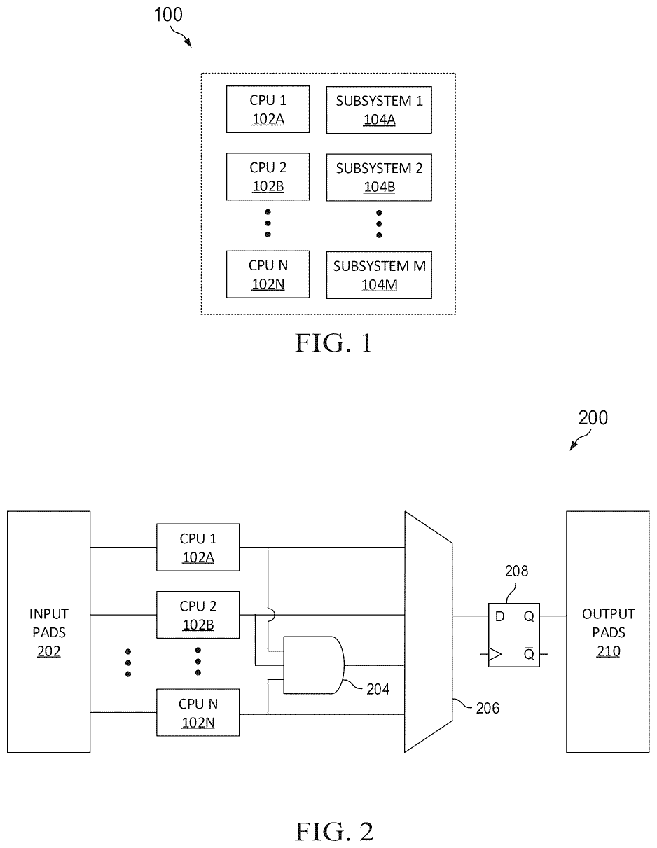

FIG. 1 illustrates a block diagram of an example system-on-chip (SoC) 100 incorporating multiple replicated processors and subsystems. The SoC 100 includes a first processor 102A, a second processor 102B, extending to an N^{th} processor 102N, and a first subsystem 104A, a second subsystem 104B, extending to an M^{th} subsystem 104M. SoC 100 may include additional replicated components or other components (e.g., memory, power management circuitry, etc.) not shown.

Generally, an SoC represents a comprehensive integration of various electronic components and functional blocks onto a single silicon die. Modern SoCs incorporate numerous specialized blocks to handle different tasks, from general-purpose computing to specific accelerated functions, making them highly versatile for various applications ranging from mobile devices to automotive systems.

In contemporary SoC designs, replication of identical blocks can serve multiple purposes. These replicated blocks can include processors, memory controllers, interface controllers (USB, PCIe, SATA), graphics processing units, neural processing units, or other specialized accelerators. The replication approach allows for parallel processing, improved performance, and enhanced system reliability through redundancy. For example, multiple identical processors can enable parallel task execution, while replicated memory controllers can increase memory bandwidth and system throughput.

Using identical replicated blocks can provide significant advantages in the design and verification process. From a design perspective, once a block is thoroughly verified and optimized, it can be replicated across the chip with confidence in its functionality. This approach can reduce design time, minimize the risk of introducing new bugs, and simplify the verification process. The layout of these blocks can be optimized once and reused multiple times, improving the efficiency of the physical design process.

Power management and thermal considerations can also benefit from block replication. Identical blocks can be selectively powered down when unused, helping manage power consumption. The regular structure created by replicated blocks can facilitate better heat distribution across the die. Additionally, in cases where fault tolerance is important, replicated blocks can provide redundancy, allowing the system to continue operating even if one block fails.

Manufacturing test and yield optimization can also benefit from block replication. When blocks are identical, test patterns developed for one instance can be reused for all instances, potentially reducing the test pattern generation effort. However, this also presents challenges in efficiently testing multiple identical blocks while maintaining the ability to identify specific failing instances, which subsequent figures address.

The processors 102A-102N represent identical replicated processor blocks within the SoC 100, where each processor shares the same internal structure, layout, and design. Each processor 102A-102N produces identical outputs when given identical inputs due to their matching architectures. This replication approach allows for efficient design and layout, as the same processor design can be duplicated multiple times across the chip.

Similarly, the subsystems 104A-104M are replicated blocks that maintain identical internal structures and layouts. Each subsystem 104A-104M responds similarly when presented with the same inputs due to their matching designs. The ability to replicate these larger subsystem blocks across the SoC 100 provides significant advantages in design efficiency and consistency of operation.

The architecture shown in FIG. 1 demonstrates how modern SoC designs can scale by replicating identical blocks, whether they are processors or larger subsystems. This approach can accommodate designs with 10 or more replicated blocks while maintaining consistent behavior. The dotted lines in the figure indicate that the number of replicated blocks can vary based on specific design requirements, with N and M representing the total number of processors and subsystems, respectively.

Testing and verifying SoC designs can present challenges, particularly when dealing with multiple identical subsystems. Design for Test (DFT) methodologies employ scan chains and test access mechanisms to verify the proper operation of the integrated circuits. The scan chains allow test patterns to be shifted into the circuits and test responses to be captured and observed through dedicated scan output pins.

For example, an existing approach employs test data compression techniques that employ a shared decompressor circuit coupled between the input pads of the SoC 100 and the inputs of multiple replicated blocks. The shared decompressor receives compressed test patterns from a limited number of input pads and expands them into full test vectors. These expanded test vectors are then distributed to the identical processors 102A-102N and subsystems 104A-104M. This approach reduces the number of input pads while maintaining test coverage.

At the output side of the replicated blocks, a shared compressor circuit combines the test responses from the processors 102A-102N and subsystems 104A-104M. The shared compressor compresses the multiple test response outputs into a smaller signature that can be transmitted through a limited number of output pads. Since the replicated blocks are identical in structure, their responses to the same test patterns should match, allowing for efficient compression of the output data.

The shared compression architecture at input and output creates a bottleneck in testing replicated blocks. When testing multiple identical blocks simultaneously, the shared decompressor distributes the same test patterns to all blocks. At the same time, the shared compressor combines all responses to allow a response from one block to go to the pads. Further, the testing time increases as each block receives and processes test patterns sequentially through the shared compression resources.

Shared compression resources also impact the ability to perform parallel testing of replicated blocks. Since all blocks receive test data through the same decompressor and send responses through the same compressor, true parallel testing cannot be achieved. This limitation becomes more pronounced as the number of replicated blocks increases in modern SoC designs.

FIG. 2 illustrates a test architecture for an embodiment system-on-chip (SoC) 200 that efficiently tests replicated processor blocks. The architecture includes input pads 202 coupled to multiple identical processors 102A-102N, where test patterns can be applied. The outputs from these processors feed into a comparison and capture network consisting of AND gate 204, multiplexer 206, and pipe flip-flop 208, with final results observable at output pads 210.

The test architecture described in FIG. 2 represents embodiments of the disclosure where processors 102A-102N are shown as example replicated blocks. The architecture can be extended to any replicated blocks or subsystems within an SoC, including but not limited to memory arrays, peripheral controllers, interface blocks, accelerators, or other functional blocks that share identical structures and layouts. The number of replicated blocks shown (N) is an example and can be scaled to accommodate any number of identical blocks based on specific SoC requirements.

The test patterns are generated and applied to processor 102A through input pads 202. The scan logic within the SoC 200 is modified to propagate identical test patterns simultaneously to processors 102B through 102N. This approach ensures that all identical processor blocks receive the same test stimulus, leveraging that these blocks share identical structures and produce matching responses.

The outputs from all processors 102A-102N are combined through AND gate 204, which compares the responses. The AND gate 204 output feeds into multiplexer 206, allowing for selective observation of the combined response or individual processor outputs. The pipe flip-flop 208 latches the selected response, providing a registered output that can be observed through output pads 210.

When a failure is detected at the output pad 210 during testing, debug capabilities can be enabled through multiplexer 206. The specific failing processor can be identified by selecting individual processor outputs one at a time and rerunning the same test patterns. This selective observation mechanism provides efficient fault isolation while maintaining the benefits of parallel testing.

The comparison and observation network comprising AND gate 204, multiplexer 206, and pipe flip-flop 208 can be replicated or modified to independently handle multiple groups of replicated blocks. The number of input pads 202 and output pads 210 may vary depending on the specific implementation requirements and the nature of the replicated blocks being tested. Additional test control and observation logic may be incorporated while maintaining the fundamental aspects of parallel pattern application and selective response observation for debugging purposes.

The architecture presented in FIG. 2 provides several significant advantages over traditional test approaches for replicated blocks in SoCs. By generating and applying test patterns to a single block and propagating them to all identical blocks simultaneously, the architecture reduces test pattern generation effort and application time. This parallel testing approach maintains complete test coverage while using minimal additional hardware.

The selective observation capability through the multiplexer 206 enables efficient debug operations without requiring separate test patterns or multiple test runs during normal operation. When a failure is detected, the ability to isolate and identify specific failing blocks through individual observation provides powerful diagnostic capabilities while maintaining the efficiency of parallel testing during normal operation.

The architecture's scalability and flexibility allow it to accommodate various types and numbers of replicated blocks without significantly modifying the basic structure. This adaptability, combined with minimal hardware overhead, makes the approach particularly valuable for complex SoCs where test time and cost are critical factors. The solution achieves an optimal balance between test efficiency, debug capability, and hardware overhead, making it particularly suitable for modern SoC designs with multiple replicated blocks.

For clarity and simplicity, the figure shows the comparison network for a single scan output from each replicated block, though in practice each block can contain multiple scan outputs. The architecture includes input pads 202 coupled to multiple identical processors 102A-102N, where test patterns can be applied. The outputs from these processors feed into a comparison and capture network consisting of AND gate 204, multiplexer 206, and pipe flip-flop 208, with final results observable at output pads 210.

The test architecture described in FIG. 2 represents embodiments of the disclosure where processors 102A-102N are shown as example replicated blocks. While only one scan output comparison network is shown, multiple such networks would be implemented for each scan output of the replicated blocks. The architecture can be extended to any replicated blocks or subsystems within an SoC, including but not limited to memory arrays, peripheral controllers, interface blocks, accelerators, or other functional blocks that share identical structures and layouts. The number of replicated blocks shown (N) is an example and can be scaled to accommodate any number of identical blocks based on specific SoC requirements.

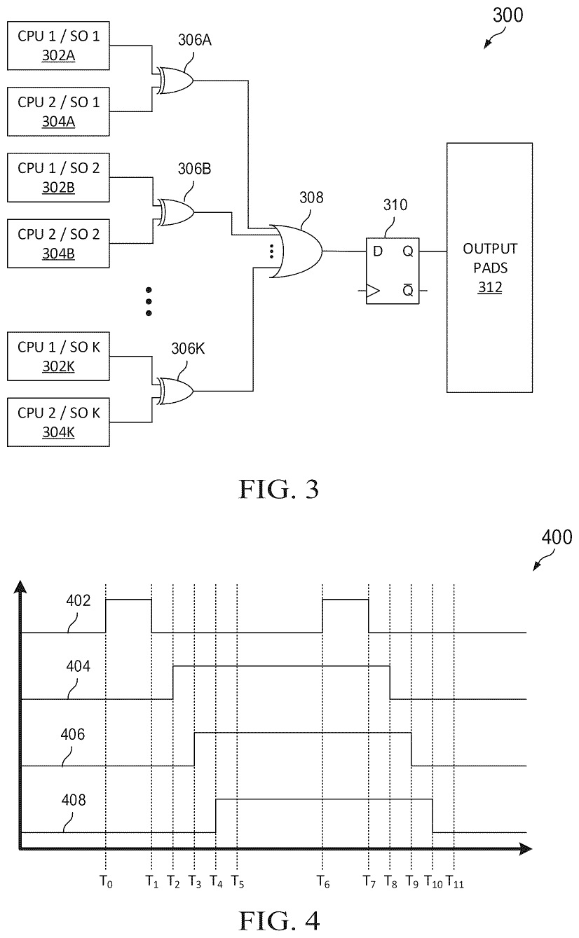

FIG. 3 illustrates an enhanced test architecture for an embodiment system-on-chip (SoC) 300 that implements XOR-based comparison logic for testing replicated processor blocks. The architecture shows corresponding scan outputs from two identical processors being compared through a series of XOR gates 306A-306K, with results combined through OR gate 308 and captured in flip-flop 310 before being observed at output pads 312.

The architecture in FIG. 3 addresses a limitation in the AND-gate-based comparison approach in FIG. 2. In traditional test architectures using AND gates for comparison, certain fault scenarios can go undetected, creating potential reliability risks in the final product.

Consider a test case where the expected output from both processors should be ‘0’. If one processor has a fault causing it to output a ‘1’ while the other processor correctly outputs ‘0’, an AND gate would produce a ‘0’ output. This ‘0’ output from the AND gate would incorrectly indicate a passing condition, as it matches the expected output value of ‘0’, despite a fault in one processor. This masking effect can lead to defective parts being incorrectly classified as good during testing.

Similarly, when testing multiple scan outputs simultaneously through an AND gate, if any single scan output from a faulty processor produces an incorrect ‘1’ when ‘0’ is expected, while all other scan outputs are correct, the AND gate masks this failure by producing a ‘0’ output. This scenario can become problematic in complex SoCs where multiple scan chains are monitored simultaneously for efficient testing.

The XOR-based comparison architecture in FIG. 3 resolves these issues by detecting any mismatch between corresponding outputs, regardless of the expected values. When corresponding scan outputs from the first processor (302A-302K) and the second processor (304A-304K) match, their respective XOR gates (306A-306K) output ‘0’. However, if any pair of corresponding outputs differ, the associated XOR gate produces a ‘1’, which propagates through OR gate 308 to indicate a failure. This ensures that no fault condition goes undetected due to logical masking effects.

In embodiments, the first processor includes scan outputs 302A-302K, while the second processor includes corresponding scan outputs 304A-304K. Each pair of corresponding scan outputs (e.g., 302A and 304A) feeds into a dedicated XOR gate (e.g., 306A). This pairing continues for all K scan output pairs, where K represents the total number of scan outputs per processor being compared, K being an integer greater than one.

The XOR gates 306A-306K perform a bit-wise comparison between corresponding scan outputs. When both inputs to an XOR gate are identical (either both ‘0’ or both ‘1’), the XOR output is ‘0’, indicating matching responses. If the inputs differ, the XOR output becomes ‘1’, indicating a mismatch. The OR gate 308 combines all XOR outputs, producing a ‘0’ when all scan output pairs match and a ‘1’ if any pair differs.

The flip-flop 310 captures the OR gate 308 output, providing a registered signal that can be observed through output pad 312. A ‘0’ at the output indicates matching responses from both processors, while a ‘1’ indicates a mismatch in at least one scan output pair, signaling a potential fault in one of the processors. This architecture provides complete coverage for detecting output mismatches between replicated blocks, regardless of the expected output values.

The architecture of FIG. 3 also provides additional diagnostic capabilities. Since each scan output pair has its own XOR gate, observing individual XOR outputs during debug operations can determine the location of mismatches. This granular comparison approach enhances fault isolation capabilities while maintaining the efficiency of parallel testing.

In embodiments, the XOR-based comparison architecture results in one additional output pad compared to the AND-gate based solution shown in FIG. 2. While both architectures use output pads to observe test results, the XOR-based approach includes a separate pad to monitor the mismatch detection signal from flip-flop 310. This additional pad represents minimal overhead, considering the improved fault detection capabilities and the total number of pads typically available in modern SoCs. The benefit of complete fault coverage through mismatch detection outweighs the cost of allocating one extra pad for test purposes.

FIG. 4 illustrates an example timing diagram 400 showing the temporal relationships between various signals in the test architecture. The diagram includes scan clock signal 402, scan output signal 404 from the first processor's first scan output, scan output signal 406 from the second processor's first scan output, and the AND gate output 408 over multiple time periods T₀ through T₁₁.

The timing diagram in FIG. 4 illustrates the operation of the comparison network shown in FIG. 2, focusing on how the AND gate 204 compares scan outputs from two replicated processors. While FIG. 2 shows the complete test architecture, including multiplexer 206 and pipe flip-flop 208, the timing diagram demonstrates the behavior of scan outputs and their comparison through AND gate 204 during test response capture.

In the context of FIG. 2's architecture, the scan clock signal 402 controls the shifting of test responses from both processors through their respective scan chains. The scan output signal 404 and the scan output signal 406 represent corresponding scan outputs from two replicated processors that feed into AND gate 204. The AND gate output 408 feeds into multiplexer 206, which can select between the combined response or individual processor outputs. The strobe points at times T₅ and T₁₁ correspond to when pipe flip-flop 208 captures the comparison results for observation through output pads 210. This relationship between the timing behavior and hardware architecture ensures proper test response comparison and observation while maintaining debug capabilities through the multiplexer selection.

The scan clock signal 402 shows two active periods, one between times T₀ and T₁ and another between times T₆ and T₇. During these periods, test responses are shifted out of the scan chains of both processors. The scan output signal 404 from the first processor and scan output signal 406 from the second processor show the respective response data being shifted out during these scan clock periods.

Between the scan clock active periods, the scan outputs from both processors demonstrate characteristic timing behavior reflecting signal propagation through their respective paths. Scan output signal 404 from the first processor transitions to a logic high at time T₂, while scan output signal 406 from the second processor transitions to a logic high at time T₃. This timing difference may result from variations in path delays between the two processors to their respective scan outputs.

The AND gate output 408 transitions to a logic high at time T₄ after scan output signal 404 and scan output signal 406 have stabilized at logic high. This behavior aligns with the logical AND operation, where the output becomes high when both inputs are high. The delay between the last input transition (scan output signal 406 at time T₃) and the AND gate output transition (at time T₄) represents the propagation delay through the AND gate 204.

Similarly, when the scan outputs return to logic low, scan output signal 404 transitions at time T₈, followed by scan output signal 406 transitioning at time T₉. The AND gate output 408 responds by transitioning to logic low at time T₁₀, reflecting the propagation delay through the AND gate 204. These timing relationships ensure proper comparison of the scan outputs while accounting for natural propagation delays in the circuit.

The timing diagram highlights two specific strobe points at times T₅ and T₁₁, where the test responses are captured and evaluated. These strobe points occur after allowing sufficient time for the scan outputs to stabilize, ensuring reliable comparison results. The AND gate output 408 behavior at these strobe points indicates whether the responses from both processors match or differ.

In one example implementation of the test architecture, significant test time reductions can be achieved on a device containing three unique types of replicated cores. A first core type, containing 4 million flops and replicated twice, reduces the test time by 13 seconds per instance. With 6.6 million flops and replicated twice, a second core type reduces the test time by 20 seconds per instance. A third core type, containing 1.6 million flops and replicated three times, reduces the test time by 4 seconds per instance. When applied to a complete device with an estimated total test time of 350 seconds, the architecture can achieve, for example, a total test time reduction of 57 seconds, demonstrating substantial improvements in test efficiency and cost savings through parallel testing of replicated blocks.

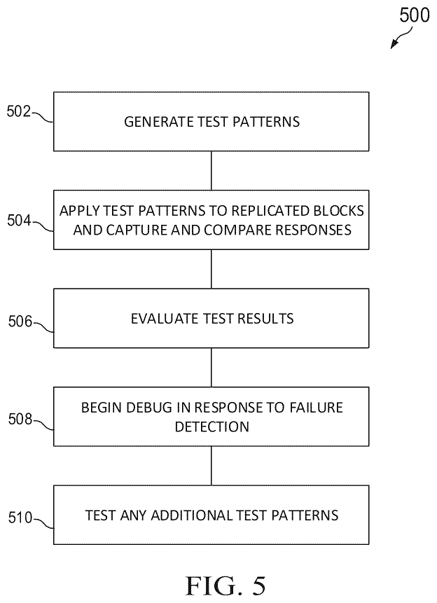

FIG. 5 illustrates a flowchart of an embodiment method 500 for operating the test architecture shown in FIG. 2. The method provides a systematic approach for testing replicated blocks while enabling efficient debug capabilities. It is noted that all steps outlined in the method are not necessarily required and can be optional. Further, changes to the arrangement of the steps, removal of one or more steps and path connections, and addition of steps and path connections are similarly contemplated.

At step 502, test patterns are generated for the first replicated block, such as processor 102A. These patterns are designed to test the functionality and detect potential manufacturing defects in the block's circuitry. Since all blocks are identical in structure and layout, the same patterns can be used to test all replicated instances, significantly reducing test pattern generation effort and storage requirements.

At step 504, test patterns are applied to all replicated blocks while simultaneously capturing and comparing responses. The generated patterns feed into all blocks through the modified scan logic, while test responses from all blocks are captured and compared through AND gate 204. As responses shift out of the scan chains of each replicated block, the AND gate 204 performs a real-time comparison, with results captured in pipe flip-flop 208 at designated strobe points. This parallel testing approach substantially reduces overall test application time compared to testing each block separately.

At step 506, the test results are evaluated by monitoring the output of pipe flip-flop 208. Failure detection triggers debug operations while passing results leads to a continuation of testing with subsequent patterns if available. This decision point determines whether detailed fault isolation is necessary.

At step 508, the debug phase begins in response to a failure being detected. The multiplexer 206 is configured to select individual outputs from replicated blocks, and the failing patterns are reapplied. The specific failing block can be identified by observing responses from each block separately. This debug capability can be particularly valuable in production testing, where identifying failing blocks can provide insights into manufacturing issues or systematic defects.

At step 510, the method determines whether additional patterns remain for testing. This step ensures complete test coverage while maintaining efficient test time through parallel pattern application. The iterative process can continue until all test patterns have been applied, providing comprehensive testing of all replicated blocks.

Advantageously, the method achieves an optimal balance between test efficiency and debug capability. The parallel testing approach significantly reduces test time, while the ability to isolate failures through individual block observation maintains thorough fault diagnosis capabilities. This methodology can be particularly effective for modern SoCs containing multiple replicated blocks, where test time reduction and precise fault isolation are crucial for manufacturing test efficiency.

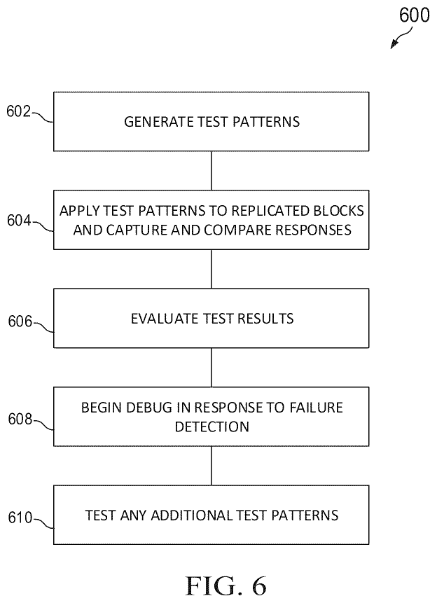

FIG. 6 illustrates a flowchart of an embodiment method 600 for operating the XOR-based test architecture shown in FIG. 3. The method provides comprehensive fault detection and isolation for replicated blocks while preventing fault masking. It is noted that all steps outlined in the method are not necessarily required and can be optional. Further, changes to the arrangement of the steps, removal of one or more steps and path connections, and addition of steps and path connections are similarly contemplated.

At step 602, test patterns are generated for a first replicated block, such as processor 302A. These patterns exercise the functionality and detect potential manufacturing defects in the block's circuitry. Since all blocks share identical structures, the same patterns test all replicated instances, significantly reducing test pattern generation effort and storage requirements. The patterns are designed to achieve maximum fault coverage while considering the parallel testing capability of the architecture.

At step 604, the test patterns are applied while performing real-time comparison of responses. As patterns feed into all replicated blocks simultaneously, corresponding scan outputs (302A-302K and 304A-304K) are compared through XOR gates 306A-306K. The XOR gates detect any mismatch between corresponding outputs, regardless of expected values, preventing fault masking that could occur with AND-gate based comparison. Simultaneously, OR gate 308 combines all XOR outputs, producing a logic ‘1’ if any mismatch occurs, and flip-flop 310 captures these results at designated strobe points for observation through output pad 312.

At step 606, the comparison results are evaluated by monitoring output pad 312. A logic ‘1’ indicates a mismatch between at least one pair of corresponding scan outputs, triggering debug operations. In contrast, a logic ‘0’ indicates matching responses, allowing testing to continue with subsequent patterns. This single-pad observation point immediately indicates any discrepancy between replicated blocks.

At step 608, when a mismatch is detected, debug operations begin by observing individual XOR gate outputs. This granular observation capability accurately identifies which scan output pairs show mismatches, facilitating efficient fault localization and diagnosis. The ability to isolate specific mismatching scan outputs provides valuable information for failure analysis and potential yield improvement.

At step 610, the method determines whether additional test patterns remain. This step manages the test flow, ensuring complete coverage of all potential fault scenarios while maintaining the efficiency of parallel testing. The process continues until all patterns have been applied and all replicated blocks are comprehensively tested.

The method achieves optimal fault detection and diagnosis capability through the XOR-based comparison approach. The parallel testing strategy and mismatch detection at the bit level ensure no faults are masked while maintaining an efficient test application. This methodology particularly suits modern SoCs with multiple replicated blocks, where both test time reduction and thorough fault detection are essential for manufacturing test quality.

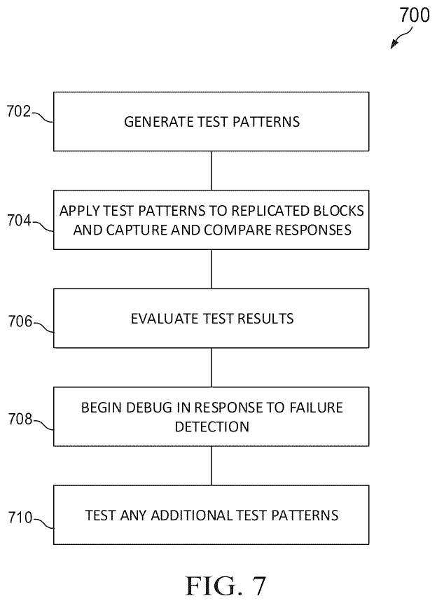

FIG. 7 illustrates a flowchart of an embodiment method 700 that combines the advantages of AND-gate and XOR-gate based architectures shown in FIGS. 2 and 3. The method leverages comparison approaches to achieve comprehensive testing while optimizing test time and fault detection. It is noted that all steps outlined in the method are not necessarily required and can be optional. Further, changes to the arrangement of the steps, removal of one or more steps and path connections, and addition of steps and path connections are similarly contemplated.

At step 702, test patterns are generated for a first replicated block. These patterns are configured to achieve maximum fault coverage while considering the parallel testing capabilities of both architectures. Since all blocks are identical in structure, the same patterns test all replicated instances. This single pattern generation approach significantly reduces test development effort and storage requirements while thoroughly testing all replicated blocks.

At step 704, the test patterns are applied while performing simultaneous comparisons through both networks. As patterns feed into all replicated blocks, responses can be evaluated concurrently through the AND gate 204 and XOR gates 306A-306K. The AND gate provides a quick pass/fail indication for matching responses, while the XOR network with subsequent OR gate detects any mismatches that could be masked by the AND gate alone. The results are captured in pipe flip-flop 208 and flip-flop 310, respectively, providing two independent verification methods.

At step 706, results from both comparison paths are evaluated. A failure detection from either the AND gate output (through pipe flip-flop 208) or the XOR-OR network output (through flip-flop 310) triggers debug operations while passing results from both paths allow testing to continue. This dual comparison approach provides enhanced confidence in test results by combining the strengths of both architectures.

At step 708, comprehensive debug operations can begin using both architectures' capabilities when a failure is detected. Multiplexer 206 enables individual block observation to identify failing blocks while the XOR network pinpoints specific mismatching scan outputs through individual XOR gate monitoring. This combined debug approach provides block-and bit-level fault isolation, enabling efficient failure analysis and diagnosis.

At step 710, the method determines whether additional test patterns remain. This step manages the test flow, ensuring complete coverage while maintaining the efficiency of parallel testing through both comparison networks. The process continues until all patterns have been applied, providing comprehensive testing with maximum fault detection capability.

The method achieves optimal fault detection and diagnosis capability by combining both comparison approaches. The parallel testing strategy, enhanced by dual comparison methods, ensures thorough fault detection while maintaining efficient test application. This methodology particularly suits complex SoCs with multiple replicated blocks, where test quality, time reduction, and precise fault isolation are all crucial factors.

While the figures and descriptions reference processors and specific subsystems as examples, embodiments of the disclosure apply to any type of replicated blocks within an integrated circuit. These replicated blocks may include, but are not limited to, memory arrays, peripheral controllers, interface blocks (such as USB, PCIe, or SATA controllers), graphics processing units, neural processing units, specialized accelerators, or any other functional circuits that are duplicated within the SoC. The number of replicated blocks shown in the figures (represented as N or M) serves as an example only and is non-limiting. Modern SoCs may incorporate, for example, ten or more identical instances of a given block, and the test architectures described herein scale to accommodate any number of replicated blocks while maintaining the benefits of parallel testing and comprehensive fault detection.

A first aspect relates to a system-on-chip (SoC), comprising a plurality of identical replicated blocks, each block having a plurality of scan outputs; a first comparison network comprising a plurality of AND gates, each AND gate having inputs coupled to corresponding scan outputs from the replicated blocks, a first multiplexer having inputs coupled to outputs of the AND gates and to individual scan outputs from the replicated blocks, and a first flip-flop having an input coupled to an output of the first multiplexer; and a second comparison network comprising a plurality of XOR gates, each XOR gate having inputs coupled to corresponding scan outputs from pairs of the replicated blocks, an OR gate having inputs coupled to outputs of the XOR gates, and a second flip-flop having an input coupled to an output of the OR gate.

In a first implementation form of the SoC, according to the first aspect as such, the first comparison network provides parallel testing capability of the replicated blocks.

In a second implementation form of the SoC, according to the first aspect as such or any preceding implementation form of the first aspect, the second comparison network prevents fault masking during testing.

In a third implementation form of the SoC, according to the first aspect as such or any preceding implementation form of the first aspect, the first multiplexer enables individual observation of scan outputs from each replicated block during debug operations.

In a fourth implementation form of the SoC, according to the first aspect as such or any preceding implementation form of the first aspect, test patterns applied to a first replicated block are simultaneously propagated to remaining replicated blocks through modified scan logic.

In a fifth implementation form of the SoC, according to the first aspect as such or any preceding implementation form of the first aspect, the second flip-flop output transitions to a logic high level in response to a mismatch between corresponding scan outputs.

In a sixth implementation form of the SoC, according to the first aspect as such or any preceding implementation form of the first aspect, the replicated blocks comprise identical processors, memory arrays, or interface controllers.

A second aspect relates to a method of testing replicated blocks in a system-on-chip (SoC), the method comprising generating test patterns for a first replicated block; simultaneously applying the test patterns to a plurality of identical replicated blocks through modified scan logic; performing first comparisons of corresponding scan outputs through AND gates; performing second comparisons of corresponding scan outputs through XOR gates; combining outputs of the XOR gates through an OR gate; capturing results of the first comparisons in a first flip-flop; capturing results of the second comparisons in a second flip-flop; and evaluating test results based on outputs of both flip-flops.

In a first implementation form of the method, according to the second aspect as such, the method further comprising detecting a failure condition; configuring a multiplexer to select individual scan outputs; and identifying a failing replicated block through individual observation.

In a second implementation form of the method, according to the second aspect as such or any preceding implementation form of the second aspect, a logic high level at the second flip-flop output indicates a mismatch between corresponding scan outputs.

In a third implementation form of the method, according to the second aspect as such or any preceding implementation form of the second aspect, the first comparisons enable parallel testing and the second comparisons prevent fault masking.

In a fourth implementation form of the method, according to the second aspect as such or any preceding implementation form of the second aspect, the method further comprising reapplying the test patterns while observing individual replicated block outputs during debug operations.

In a fifth implementation form of the method, according to the second aspect as such or any preceding implementation form of the second aspect, the replicated blocks comprise identical processors, memory arrays, or interface controllers.

In a sixth implementation form of the method, according to the second aspect as such or any preceding implementation form of the second aspect, combining the outputs of the XOR gates detects any mismatch between corresponding scan outputs regardless of expected values.

A third aspect relates to a design for test (DFT) architecture for testing a system-on-chip (SoC) with a plurality of scan chains distributed across identical replicated blocks, the DFT architecture comprising a first comparison network providing parallel test capability through AND gates coupled to corresponding scan outputs from the replicated blocks; a second comparison network preventing fault masking through XOR gates coupled to corresponding scan outputs from pairs of the replicated blocks; selection logic enabling individual observation of replicated block outputs during debug operations; and capture logic registering results from both comparison networks.

In a first implementation form of the design for test architecture, according to the first aspect as such, the second comparison network further comprises an OR gate combining outputs from the XOR gates to generate a mismatch detection signal.

In a second implementation form of the design for test architecture, according to the third aspect as such or any preceding implementation form of the third aspect, the selection logic comprises a multiplexer having inputs coupled to outputs of the AND gates and to individual scan outputs from the replicated blocks.

In a second implementation form of the design for test architecture, according to the third aspect as such or any preceding implementation form of the third aspect, the capture logic comprises a first flip-flop capturing results from the first comparison network; and a second flip-flop capturing results from the second comparison network.

In a third implementation form of the design for test architecture, according to the third aspect as such or any preceding implementation form of the third aspect, the design for test architecture further comprising modified scan logic propagating test patterns simultaneously to all replicated blocks.

In a fourth implementation form of the design for test architecture, according to the third aspect as such or any preceding implementation form of the third aspect, the replicated blocks comprise identical processors, memory arrays, or interface controllers.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. A system-on-chip (SoC), comprising:
a plurality of identical replicated blocks, each block having a plurality of scan outputs;
a first comparison network comprising:
a plurality of AND gates, each AND gate having inputs coupled to corresponding scan outputs from the replicated blocks,
a first multiplexer having inputs coupled to outputs of the AND gates and to individual scan outputs from the replicated blocks, and
a first flip-flop having an input coupled to an output of the first multiplexer; and
a second comparison network comprising:
a plurality of XOR gates, each XOR gate having inputs coupled to corresponding scan outputs from pairs of the replicated blocks,
an OR gate having inputs coupled to outputs of the XOR gates, and
a second flip-flop having an input coupled to an output of the OR gate.

2. The SoC of claim 1, wherein the first comparison network provides parallel testing capability of the replicated blocks.

3. The SoC of claim 1, wherein the second comparison network prevents fault masking during testing.

4. The SoC of claim 1, wherein the first multiplexer enables individual observation of scan outputs from each replicated block during debug operations.

5. The SoC of claim 1, wherein test patterns applied to a first replicated block are simultaneously propagated to remaining replicated blocks through modified scan logic.

6. The SoC of claim 1, wherein the second flip-flop output transitions to a logic high level in response to a mismatch between corresponding scan outputs.

7. The SoC of claim 1, wherein the replicated blocks comprise identical processors, memory arrays, or interface controllers.

8. A method of testing replicated blocks in a system-on-chip (SoC), the method comprising:
generating test patterns for a first replicated block;
simultaneously applying the test patterns to a plurality of identical replicated blocks through modified scan logic;
performing first comparisons of corresponding scan outputs through AND gates;
performing second comparisons of corresponding scan outputs through XOR gates;
combining outputs of the XOR gates through an OR gate;
capturing results of the first comparisons in a first flip-flop;
capturing results of the second comparisons in a second flip-flop; and
evaluating test results based on outputs of both flip-flops.

9. The method of claim 8, further comprising:
detecting a failure condition;
configuring a multiplexer to select individual scan outputs; and
identifying a failing replicated block through individual observation.

10. The method of claim 8, wherein a logic high level at the second flip-flop output indicates a mismatch between corresponding scan outputs.

11. The method of claim 8, wherein the first comparisons enable parallel testing and the second comparisons prevent fault masking.

12. The method of claim 8, further comprising reapplying the test patterns while observing individual replicated block outputs during debug operations.

13. The method of claim 8, wherein the replicated blocks comprise identical processors, memory arrays, or interface controllers.

14. The method of claim 8, wherein combining the outputs of the XOR gates detects any mismatch between corresponding scan outputs regardless of expected values.

15. A design for test (DFT) architecture for testing a system-on-chip (SoC) with a plurality of scan chains distributed across identical replicated blocks, the DFT architecture comprising:
a first comparison network providing parallel test capability through AND gates coupled to corresponding scan outputs from the replicated blocks;
a second comparison network preventing fault masking through XOR gates coupled to corresponding scan outputs from pairs of the replicated blocks;
selection logic enabling individual observation of replicated block outputs during debug operations; and
capture logic registering results from both comparison networks.

16. The design for test architecture of claim 15, wherein the second comparison network further comprises an OR gate combining outputs from the XOR gates to generate a mismatch detection signal.

17. The design for test architecture of claim 15, wherein the selection logic comprises a multiplexer having inputs coupled to outputs of the AND gates and to individual scan outputs from the replicated blocks.

18. The design for test architecture of claim 15, wherein the capture logic comprises:
a first flip-flop capturing results from the first comparison network; and
a second flip-flop capturing results from the second comparison network.

19. The design for test architecture of claim 15, further comprising modified scan logic propagating test patterns simultaneously to all replicated blocks.

20. The design for test architecture of claim 15, wherein the replicated blocks comprise identical processors, memory arrays, or interface controllers.
